(19) United States
(12) Patent Application Publication
(10) Pub. No.: US 2024/0413232 A1
(43) Pub. Date: Dec. 12, 2024

(54) HIGH PERFORMANCE FETS

(71) Applicant: Samsung Electronics Co., Ltd., Suwon-si (KR)

(72) Inventors: Mehdi Saremi, Danville, CA (US); Aravindh Kumar, Mountain View, CA (US); Rebecca Park, Mountain View, CA (US); Muhammed Ahosan Ul Karim, San Jose, CA (US); Ming He, San Jose, CA (US); Harsono Simka, Saratoga, CA (US)

(21) Appl. No.: 18/356,776

(22) Filed: Jul. 21, 2023

Related U.S. Application Data
(60) Provisional application No. 63/471,428, filed on Jun. 6, 2023.

(51) Int. Cl. H01L 29/775; H01L 21/02; H01L 21/3065; H01L 29/06; H01L 29/423; H01L 29/66; H01L 29/786

(52) U.S. Cl. CPC H01L 29/775; H01L 21/02532; H01L 21/02639; H01L 21/3065; H01L 29/0673; H01L 29/42392; H01L 29/66439; H01L 29/78696

(57) ABSTRACT

According to one or more embodiments of the present disclosure, a semiconductor device is described. The semiconductor device may include a substrate, a channel portion on the substrate between a source region and a drain region, and a gate on the channel. The channel portion may include a first portion extending in a first direction and at least one second portion protruding from the first portion in a second direction crossing the first portion.

### CROSS-REFERENCE TO RELATED APPLICATION(S)

This application claims priority to and the benefit of U.S. Provisional Patent Application No. 63/471,428 filed on Jun. 6, 2023, which is incorporated herein by reference in its entirety.

### FIELD

The present application relates to field effect transistors (FETs), and more particularly to high performance FETs.

### BACKGROUND

Field effect transistors (FETs) technology has improved over the years to more densely pack FETs on chips by reducing the size of individual FETs as well as changing the structure of the FETs during fabrication. FinFETs and nanosheet (NS) FETs are a few examples of these advancements. However, some of these new techniques are faced with new challenges that were not apparent in planar structured FETs. Therefore, further improvements in FETs and processes for their fabrication are desired.

### SUMMARY

According to one or more embodiments of the present disclosure, a semiconductor device may include: a substrate; a channel portion on the substrate between a source region and a drain region, the channel portion including a first portion extending in a first direction and at least one second portion protruding from the first portion in a second direction crossing the first portion; and a gate on the channel.

The first portion may include a first fin extending in the first direction, and the at least one second portion may include a plurality of second fins spaced from each other along the first direction.

The source region may be coupled to a first end of the channel portion and the drain region is coupled to the second end of the channel portion, such that in response to a bias voltage applied to the gate, charge carriers flow between the source region and the drain region via the channel portion.

A lowermost surface of the channel portion may be directly coupled to the substrate.

The channel portion may include silicon (Si).

The first fin of the channel portion may have a surface orientation of 110 and the plurality of second fins has a surface orientation of 100.

According to one or more embodiments of the present disclosure, a metal-oxide semiconductor field-effect transistor (MOSFET) may include the semiconductor device.

According to one or more embodiments of the present disclosure, an integrated circuit may include the MOSFET.

According to one or more embodiments of the present disclosure, a method is described. The method may include: growing a superlattice epitaxy structure, the superlattice epitaxy structure including more than one first epitaxy layers and at least one second epitaxy layer grown alternatingly one over another; etching the more than one first epitaxy layers from the superlattice epitaxy structure; depositing a mask at a first side and a second side of the at least one second epitaxy layer such that a center portion of the at least one second epitaxy layer is unmasked; and growing a third epitaxy layer on the at least one second epitaxy layer at the unmasked center portion.

A lowermost layer of the superlattice epitaxy structure and an uppermost layer of the superlattice epitaxy structure may be the more than one first epitaxy layers.

The more than one first epitaxy layers may include silicon germanium having a suitable concentration ratio of silicon to germanium, and the at least one second epitaxy layer may include silicon.

The at least one second epitaxy layer may include pure silicon.

The etching may include performing a selective dry etching process configured to selectively remove material having the suitable concentration ratio of silicon to germanium.

The at least one second epitaxy layer may form a second fin in a second direction of a metal-oxide semiconductor field effect transistor (MOSFET) channel.

The third epitaxy layer may form a first fin extending in a first direction of the MOSFET channel, the second fin protruding from the first fin in the second direction and crossing the first fin.

According to one or more embodiments of the present disclosure, a method may include: depositing a mask at a center portion of a silicon layer; removing unmasked portions of the silicon layer; growing a superlattice epitaxy structure at a first side and a second side of the silicon layer, the superlattice epitaxy structure including more than one first epitaxy layers and at least one second epitaxy layer grown alternatingly one over another, the at least one second epitaxy layer being a silicon layer; and etching the more than one first epitaxy layers from the superlattice epitaxy structure.

A lowermost layer of the superlattice epitaxy structure and an uppermost layer of the superlattice epitaxy structure may be the more than one first epitaxy layers, and the more than one first epitaxy layers may include silicon germanium having a suitable concentration ratio of silicon to germanium.

The etching may include performing a selective dry etching process configured to selectively remove material having the suitable concentration ratio of silicon to germanium.

The at least one second epitaxy layer may form a second fin in a first direction of a metal-oxide semiconductor field effect transistor (MOSFET) channel.

The silicon layer may form a first fin extending in a first direction of the MOSFET channel, the second fin protruding from the first fin in the second direction and crossing the first fin.

The scope of the invention is defined by the claims, which are incorporated into this section by reference. A more complete understanding of embodiments of the invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIG. 1 is a circuit diagram of a field effect transistor (FET).

FIG. 2 is a perspective view of a Fin field effect transistor (FinFET), according to related art.

FIG. 3 is a perspective view of a nanosheet (NS) or gate-all-around (GAA) FET, according to related art.

FIG. 4 is a perspective view of a combined Fin+NS FET, according to one or more embodiments of the present disclosure.

FIG. 5A is a cross-sectional view in the x-y plane of the channel of the FinFET, according to related art.

FIG. 5B is a cross-sectional view in the z-y plane of the channel of the FinFET, according to related art.

FIG. 6A is a cross-sectional view in the x-y plane of a channel of the NS FET, according to related art.

FIG. 6B is a cross-sectional view in the z-y plane of the channel of the NS FET, according to related art.

FIG. 7A is a cross-sectional view in the x-y plane of a channel of the Fin+NS FET, according to one or more embodiments of the present disclosure.

FIG. 7B is a cross-sectional view in the z-y plane of the channel of the Fin+NS FET, according to one or more embodiments of the present disclosure.

FIGS. 8A-8D illustrate a process for manufacturing the channel of the Fin+NS FET, according to one or more embodiments.

FIG. 9 is a flow chart of the process for manufacturing the channel of the Fin+NS FET illustrated in FIGS. 8A-8D, according to one or more embodiments of the present disclosure.

FIGS. 10A-10D illustrate another process for manufacturing the channel of the Fin+NS FET, according to one or more embodiments of the present disclosure.

FIG. 11 is a flow chart of the process for manufacturing the channel of the Fin+NS FET illustrated in FIGS. 10A-10D, according to one or more embodiments of the present disclosure.

FIG. 12 is an example system diagram of an electronic system that may utilize one or more electronic devices, according to one or more embodiments of the present disclosure.

Embodiments of the present disclosure and their aspects and features are best understood by referring to the detailed description that follows. Unless otherwise noted, like reference numerals denote like elements throughout the attached drawings and the written description, and thus, descriptions thereof may not be repeated. In the drawings, the relative sizes of elements, layers, and regions may be exaggerated for clarity.

### DETAILED DESCRIPTION

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices such as field programmable gate arrays (FPGAs).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As more transistors are packed into smaller microprocessors and memory chips, FinFETs and stacked NS FETs may be used because of their scalability and compact sizes. However, with the growing demand for further scaling of the transistors, FinFETs and NS FETs may face new challenges. For example, because of the relatively high aspect ratio of the tall and narrow fin shaped channels of the FinFETs, accurate lithography of such fins has become difficult. An alternative to the FinFETs are the NS FETs due to their improved electrostatics and improved short-channel control. However, scaling the nanostacks to a 5-track cell height and beyond has been difficult, and dominant (100) surface orientation of the silicon (Si) channel makes unbalanced n-channel metal-oxide semiconductor (NMOS) and p-channel metal-oxide semiconductor (PMOS) drive current, which leads to some CMOS design challenges. Accordingly, one or more embodiments of the present disclosure contemplates FETs that implement a combination of FinFETs and NS FETs to overcome some of these challenges.

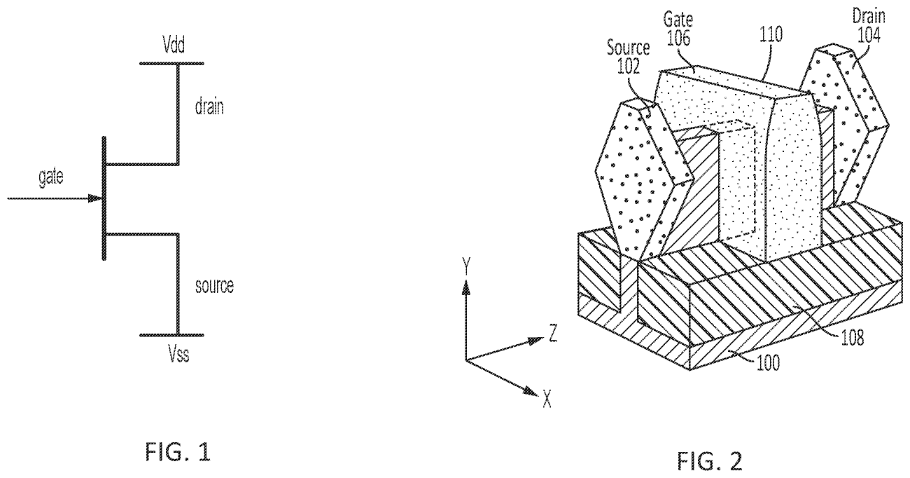

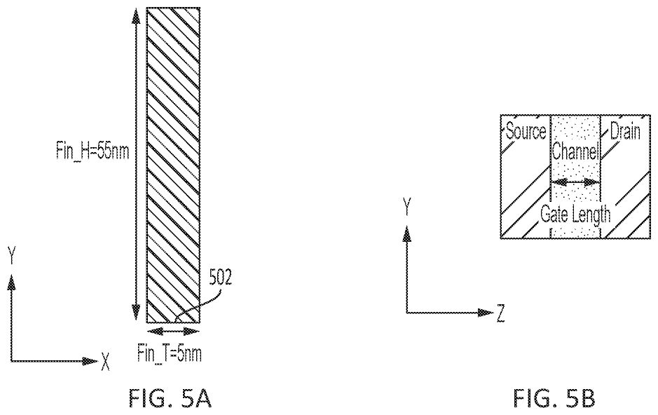

Transistors such as FinFETs, NS FETs, and other FETs that will be later described throughout the present disclosure may be illustrated in a circuit diagram using a schematic symbol of a FET as shown in FIG. 1. FIG. 2 is a perspective view of a FinFET, according to related art. A FinFET may include a substrate 100, an oxide layer 108, a source 102, a drain 104, a fin-shaped channel 110, and a gate 106 surrounding the channel 110. In one or more embodiments, the substrate 100 may be made of a silicon material (e.g., silicon wafer), and the related art FinFET device may be manufactured according to fabrication techniques known in the art. Accordingly, the fin-shaped channel 110 may be fabricated on the substrate 100 and may have a tall and narrow cross-sectional structure in the x-y plane as shown in FIG. 5A. Furthermore, the channel 110 may extend in the z-axis direction connecting, and thereby creating a channel between the source 102 and the drain 104. In some related art, the gate 106 may cover three sides of the channel 110. That is, the gate may 106 cover the top and the two sides of the channel 110. The bottom of the channel 110 may not be covered because the lower surface of the channel 110 may be on the substrate 100.

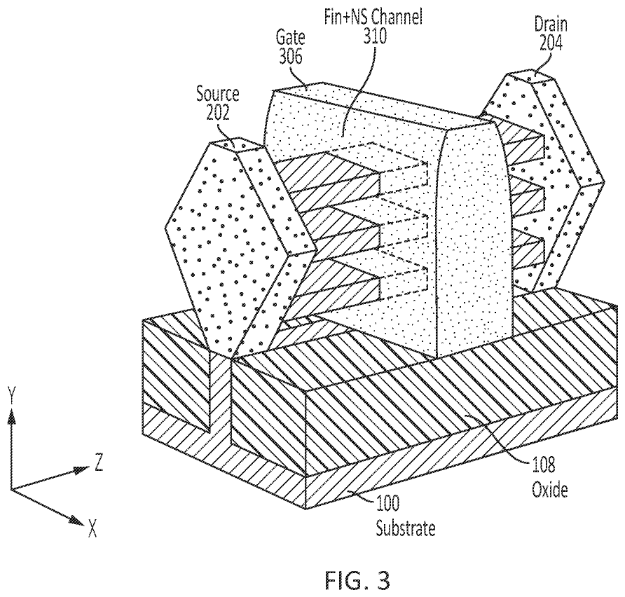

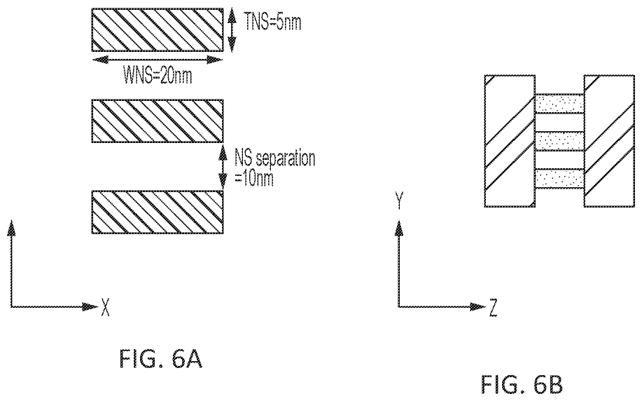

FIG. 3 is a perspective view of a nanosheet (NS) or gate-all-around (GAA) FET, according to related art. The NS FET may include a substrate 100, an oxide layer 108, a source 302, a drain 304, a plurality of nanosheet channels 310, and a gate 306 surrounding the plurality of nanosheet channels 110. A plurality of nanosheets may be stacked one over another with some distance therebetween to form channels between the source 302 and the drain 304. A cross-sectional view of the channels of a NS FET is shown in FIG. 6A. The gate 306 may be formed all around the channels formed by the nanosheets, thereby covering all four sides (or surfaces) of each one of the nanosheets. Accordingly, NS FETs may have a different short-channel effect compared to FinFETs. However, stacking a plurality of nanosheets one over another may become challenging when it is scaled to a 5-track cell height or beyond. A “cell height” may correspond to a pitch×N, where N represents the number of tracks. Therefore, by way of example, “5-track” means that N is equal to 5, and the pitch may refer to a distance from a first horizontal metal portion of the FET to the next horizontal metal portion.

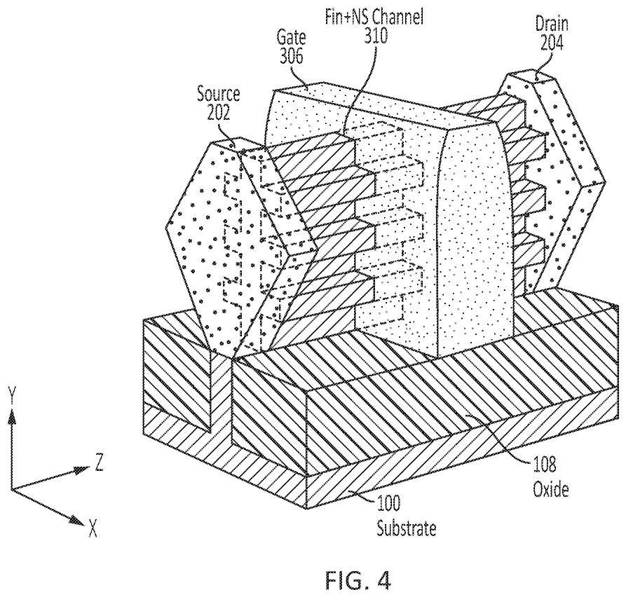

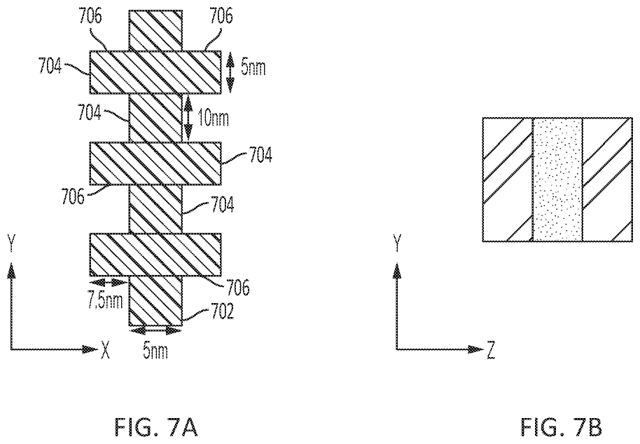

According to one or more embodiments of the present disclosure, the channel structure in a FinFET and the channel structure in a NS FET may be combined to form a fishbone structure (e.g., a channel structure having a first portion (or a first fin) extending in a first direction and at least one second portion (or at least one second fin) protruding from the first portion in a second direction crossing the first direction) to overcome some of the challenges associated with the FinFETs and the NS FETs. FIG. 4 is a perspective view of a combined Fin+NS FET (i.e., Fin plus NS FET), according to one or more embodiments of the present disclosure. Similar to the FinFET in FIG. 1 or the NS FET in FIG. 3, the Fin+NS FET may have a substrate 100 and an oxide layer 108 on the substrate 100. However, the channel 310 of the Fin+NS FET between the source 302 and the drain 304 may have a fishbone structure as shown in a cross-sectional view on the x-y plane in FIG. 7A. In other words, when viewed on the x-y plane (or in a planar view on the x-y plane), the channel 310 may have a structure similar to a fishbone including a substantially thin and narrow high aspect ratio shape as in a FinFET and the plurality of stacked nanosheets as in the channels of a NS FET combined together. For purposes of describing the structure and the various embodiments in the present disclosure, the portion of the channel that looks like the FinFET channel may be referred to as a vertical fin portion when viewed from the x-y plane, and the portion of the channel that looks like the NS FET channel may be referred to as the horizontal cross-fins when viewed from the x-y plane. Thus, when the vertical fin and the horizontal cross-fin are combined, they form the fishbone structured channel 310 of the Fin+NS FET.

In one or more embodiments, a gate 306 may cover all surfaces around the perimeter of the fishbone structured channel 310 except the bottom surface. The bottom surface of the channel 310 may be on (e.g., directly on) the substrate 110, and therefore any heat from the channel 310 may be dissipated to the substrate 100. In one or more embodiments, the source 302 and the drain 304 may be a block (e.g., a substantially diamond-like or a substantially rectangular shaped block) as shown in FIG. 4 but other shapes and sizes may be envisaged. Furthermore, the fishbone channel (i.e., the channel or the channel portion having the fishbone structure) 310 may extend along the z-axis from the source 302 to the drain 304 such that when the gate 306 is biased with a voltage during operation, the channel 310 may carry the charge carrier (e.g., drive current generated by a movement of holes and/or electrons) between the source 302 and the drain 304.

More details of the channels will now be described with reference to FIGS. 5-7. FIG. 5A is a cross-sectional view in the x-y plane of the channel of the FinFET, according to related art, and FIG. 5B is a cross-sectional view in the z-y plane of the channel of the FinFET, according to related art. As previously discussed, the channel of a FinFET may be covered by a gate along three side (or surfaces) of the channel because the bottom surface 502 of the channel may be on the substrate. Accordingly, an effective channel width (Weff) of the FinFET channel may be just the sum of the two side surfaces and the top surfaces. Therefore, according to the example dimensions illustrated for the channels of a FinFET in FIG. 5A, the Weff may be computed as 115 nm (e.g., 55 nm+5 nm+55 nm).

FIG. 6A is a cross-sectional view in the x-y plane of the channel of the NS FET, according to related art, and FIG. 6B is a cross-sectional view in the z-y plane of the channel of the NS FET, according to related art. Differently from the channels of the FinFET, the gate may cover all four surfaces of each nanosheet channel because all of the nanosheets are spaced (e.g., spatially and thermally isolated) from the substrate. Because the gate surrounds all around each of the nanosheets, the Weff may be computed by computing the perimeters of all of the nanosheets. In this case, Weff may be computed as 150 nm because there are three nanosheets and each nanosheet may have a Weff of 50 nm (e.g., 5 nm+20 nm+5 nm+20 nm). Accordingly, the Weff of the NS FET is greater than the Weff for the FinFET, and therefore the NS FET may result in a larger drive current through the NS FET compared to the FinFET. The Weff may be increased by adjusting other elements such as, for example, increasing the cell height (e.g., the number of nanosheets), or increasing the dimensions of each individual nanosheets. The Weff may be further increased by combining the channel structures of the FinFET and the NS FET, according to one or more embodiments of the present disclosure. Additionally, because the nanosheets are spaced (e.g., spatially and thermally isolated) from each other and from the substrate, the nanosheets may experience a self-heating effect where in operation, during which the nanosheets may generate heat with little to no place for the heat to dissipate. That is, even though the nanosheets may be connected to the source and drain, it may take substantially a long time for the heat to dissipate from local high-temperature spots within the channel. This may be particularly noticeable when the NS FET is configured to operate having a relatively high biasing voltage such as with the Vds and Vgs biasing points. Therefore, local hotspots and temperatures differences between the different nanosheet channels may cause the NS FET to behave unreliably over time. Therefore, techniques for more evenly distributing and/or dissipating heat may improve the performance of the FET.

FIG. 7A is a cross-sectional view in the x-y plane of the channel of the Fin+NS FET, according to one or more embodiments of the present disclosure, and FIG. 7B is a cross-sectional view in the z-y plane of the channel of the Fin+NS FET, according to one or more embodiments of the present disclosure. As can be seen, the Weff of the fishbone structure formed by combining the vertical fin of the FinFET and the horizontal cross-fins of the NS channels, is substantially larger at 205 nm in comparison to the related art Fin structure or the related art NS structure. For example, the Weff may be computed by summing the surfaces around the perimeter of the channel except the bottom surface 702 of the channel because this portion may be on (e.g., directly on) the substrate.

Accordingly, the Weff of the Fin+NS FET may be 37% larger than the Weff of the NS FET and nearly twice that of the FinFET. Furthermore, because the channels are all interconnected with each other, heat may be distributed more evenly across the channel and it may be dissipated to the substrate via the bottom surface 702 of the channel that is connected to the substrate, therefore reducing or preventing the self-heating effect associated with the NS FETs.

In one or more embodiments, the surface orientation of the FinFET channel is (110), which has a relatively balanced drive current between PMOS devices and NMOS devices. On the other hand, the surface orientation of the NS FET channels is (100), which has a more unbalanced drive current between the PMOS and NMOS devices. In other words, the drive current for an NMOS is much larger than the drive current for the PMOS when the surface orientation is (100). However, because the Fin+NS FET channels combines the FinFET channel and the NS FET channel to form the fishbone structured channel, the Fin+NS FET channel may have both (100) and (110) surface orientations. For example, the vertical surfaces 704 (as oriented in the drawings in FIG. 7A) may have a surface orientation of (110) and the horizontal surfaces 706 may have a surface orientation of (100). Accordingly, the difference in the drive current between the PMOS and NMOS devices may be reduced, thereby providing a more balanced drive current across the Fin+NS FETs. It should be noted that while the Fin+NS FET channel illustrated in FIG. 7A shows three horizontal cross-fins and one vertical fin, more or fewer number of horizontal cross-fins may be formed, for example two or four or five. Accordingly, the Weff may be increase or decrease, which may ultimately result in larger or smaller drive current, respectively. Furthermore, the illustrated dimensions are mere examples, and that larger or smaller dimensions may be contemplated, which may also increase or decrease the Weff and the drive current.

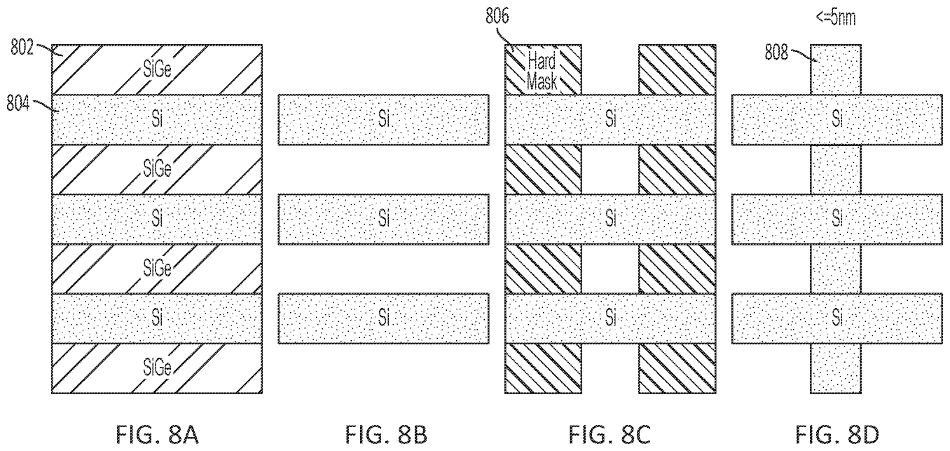

FIGS. 8A-8D illustrate a process for manufacturing the channel of the Fin+NS FET, according to one or more embodiments of the present disclosure. As shown in FIG. 8A, a superlattice epitaxy structure (or epitaxial layers) may be formed according to one or more epitaxy growing techniques known by persons having ordinary skill in the art. For example, a silicon germanium (SiGe) may first be grown, followed by growing a pure silicon (Si) crystalline layer over the SiGe layer. In one or more other embodiments, the superlattice epitaxy structure may be grown using other elements for epitaxy growing known in the art. This process may be repeated a number of time until the desired superlattice is formed, for example a superlattice that includes four layers of SiGe and Si as shown in FIG. 8A. Furthermore, it should be noted that the lowermost layer and the uppermost layer may be the SiGe layer so that the desired fishbone structure may be formed, which will be apparent later in the present disclosure. In one or more embodiments, the SiGe may have suitable concentration ratios (e.g., predetermine concentration ratios to support selective etching), for example 50% Si and 50% Ge, or 25% Si and 75% Ge, or 75% Si and 25% Ge, etc.

At FIG. 8B, the SiGe layer may be etched away, for example, by utilizing selective dry and/or chemical etching. Selective etching may be performed by utilizing an etching technique that substantially removes primarily (e.g., only) the material that includes a suitable or specified concentration ratio of silicon to germanium. This way, primarily (e.g., only) the targeted (or desired) layers having the suitable or specified silicon to germanium concentration ratio are substantially removed. Accordingly, after the selective etching process is performed, the Si layers (e.g., only the Si layers) may remain (or may substantially remain) as shown in FIG. 8B. Next, at FIG. 8C, a mask (e.g., hard mask) may be deposited on the remaining Si layers at a first side and a second side of the

Si layer. For example, as shown, the mask may be deposited along the outer edges of the Si layer, thereby leaving the center portion or center area of the Si layer unmasked and exposed. In one or more embodiments, the hard mask may be made of any type of mask that is known in the art, for example, a physical mask, and is utilized to physically or chemically block the portions of the Si layer that are covered by the mask.

Finally, at FIG. 8D, another Si epitaxy layer may be grown on the existing Si layer. Because of the mask 806 that is on the Si layer, the Si from the epitaxy process grows (e.g., grows only) at the unmasked portions. After the Si epitaxy layer is grown, the mask may be removed, for example, by etching or selectively etching away the mask. Once the mask is removed, the result is the fishbone structured channel for the Fin+NS FET.

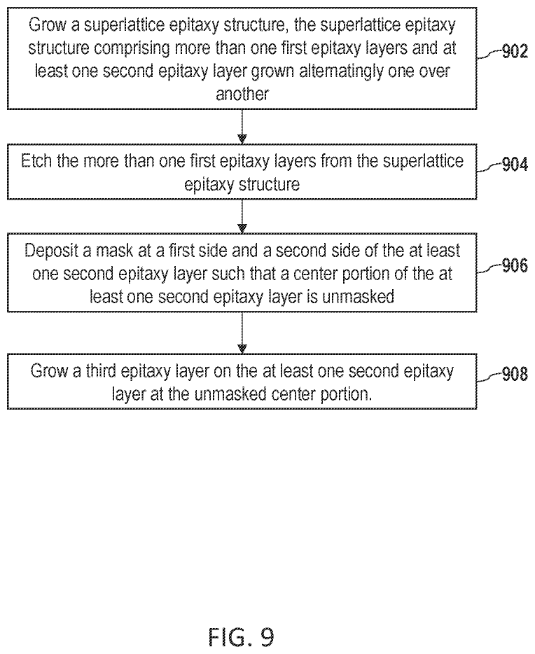

FIG. 9 is a flow chart of the process for manufacturing the channel of the Fin+NS FET illustrated in FIGS. 8A-8D, according to one or more embodiments. At step 902, a superlattice epitaxy structure may be grown, for example on a substrate. The superlattice epitaxy structure may include more than one first epitaxy layers and at least one second epitaxy layer grown alternatingly one over another. For example, a superlattice of alternating layers may be grown by an epitaxy process. In one or more embodiments, the superlattice may be made of SiGe and Si, whereby the SiGe is the lowermost layer and the uppermost layer of the superlattice. Accordingly, in some embodiments, there may be an even number of the first epitaxy layer (e.g., the SiGe layer) and an odd number of the second epitaxy layer (e.g., the Si layer) corresponding to a number that is one less than the number of the first epitaxy layer. That is, if there are four first epitaxy layers, then there should be three second epitaxy layers. But the embodiments are not limited thereto. For example, in one or more other embodiments, there may be an even number of the first epitaxy layer (e.g., the SiGe layer) and an even number of the second epitaxy layer (e.g., the Si layer). Yet in other embodiments, there may be an odd number of the first epitaxy layer (e.g., the SiGe layer) and an even number of the second epitaxy layer (e.g., the Si layer), or an odd number of the first epitaxy layer (e.g., the SiGe layer) and an odd number of the second epitaxy layer (e.g., the Si layer). Accordingly, superlattice epitaxy structure may be grown or formed.

At step 904, after the superlattice epitaxy structure is grown or formed, the more than one first epitaxy layers from the superlattice epitaxy structure may be etched away or removed. Any suitable etching technique may be utilized, for example, dry etching or wet etching to selectively etch primarily the desired or targeted layer of the superlattice epitaxy structure (e.g., the first epitaxy layers). Then, at step 906, a mask may be deposited a first side and a second side of the at least one second epitaxy layer (e.g., the layer that remains and was not etched away) such that a center portion of the at least one second epitaxy layer is unmasked. Finally, at step 908, a third epitaxy layer may be grown on the at least one second epitaxy layer at the unmasked center portion of the second epitaxy layer. In other words, the third epitaxy layer may be grown in the space between the mask that is at the first side and the second side of the second epitaxy layer and in the case that there are two or more second epitaxy layers (e.g., there are three second epitaxy layers shown in FIG. 8D), then also between the multiple second epitaxy layers. Accordingly, the fishbone structure channel formed primarily of pure silicon may be fabricated. Yet in one or more embodiments, the fishbone structure channel may be formed with other materials such as, for example, SiGe, Ge, or other suitable channel materials by changing the materials used for the superlattice epitaxy structure and selective etching described above.

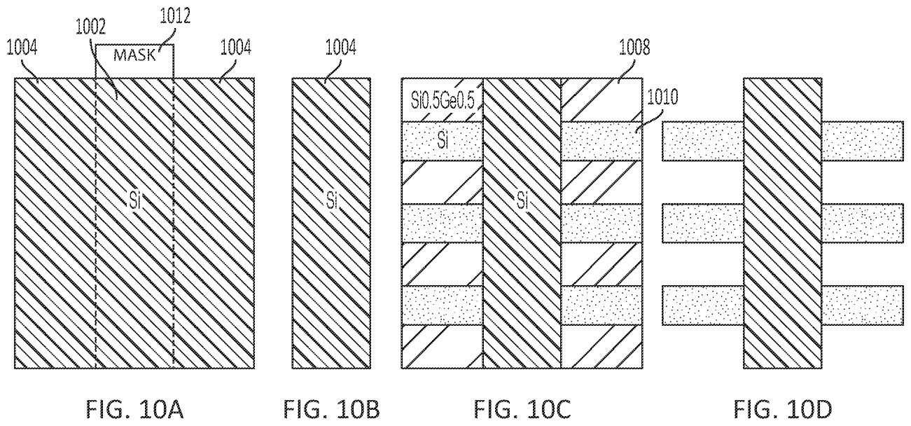

FIGS. 10A-10D illustrate another process for manufacturing the channel of the Fin+NS FET, according to one or more embodiments. As shown in FIG. 10A, a bulk pure crystalline silicon 1002 may be formed or provided according to one or more techniques for silicon growth known to persons having ordinary skill in the art. A mask 1012 may be deposited on the silicon 1002 and the outer portions 1004 of the silicon 1002 may be etched to form a thin and narrow silicon portion 1006 having a relatively high aspect ratio as shown in FIG. 10B. In other words, the silicon 1006 shown in FIG. 10B may be formed by using, for example, a hard mask to block the center portion of the silicon 1002 from being etched and the outer portions 1004 may be removed by an etching process, thereby resulting in the high aspect ratio silicon pillar 1006 shown in FIG. 10B.

Once the silicon pillar 1006 is formed, a superlattice may be formed on both outer sides of the silicon pillar 1006 by performing a series of epitaxial processes to grow multiple layers of Si layers 1010 and SiGe layers 1008. More specifically, a hard mask may be placed on the silicon pillar 1006 and a first Si layer 1008 may be grown. Then the SiGe layer 1010 may be grown on top of the first Si layer 1008. This process may be repeated until the desired number of Si layer 1010 and SiGe layers 1008 are formed as shown in FIG. 10C. Next, a selective etching process may be performed to primarily remove (e.g., remove only) the SiGe layer 1010. In other words, the etching process is performed such that primarily (e.g., only) the specifically targeted layer, e.g., the SiGe layer 1010, is removed, thus substantially leaving (e.g., leaving) behind the Si layer 1008. In one or more embodiments, the etching process may be a dry etching process or a chemical etching process. The SiGe may be, for example, 50% Si and 50% Ge, or 25% Si and 75% Ge, or 75% Si and 25% Ge, etc. Thus, selective etching process will primarily remove (e.g., remove only) the SiGe having the precise Si to Ge ratio. Accordingly, once the SiGe layer 1010 is substantially removed (e.g., removed), what substantially remains (e.g., remains) is the fishbone structured channel for the Fin+NS FET made out of pure Si as shown in FIG. 10D.

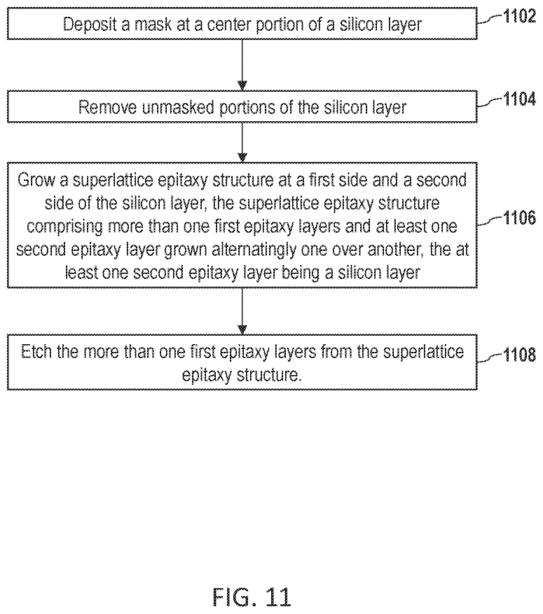

FIG. 11 is a flow chart of the process for manufacturing the channel of the Fin+NS FET illustrated in FIGS. 10A-10D, according to one or more embodiments. Accordingly, a block of bulk pure silicon semiconductor may be provided as a silicon layer starting point. At step 1102, a mask may be deposited at a center portion or region at a top or upper surface of the silicon layer. At step 1104, the unmasked portions of the silicon layer may be removed according to any one or more known techniques for removing silicon such as etching. Accordingly, a substantially narrow and tall, high aspect ratio silicon pillar is created. Then, step 1106, a superlattice epitaxy structure may be grown at a first side and a second side of the silicon layer (e.g., silicon pillar). The superlattice epitaxy structure may include more than one first epitaxy layers and at least one second epitaxy layer grown alternatingly one over another. In one or more embodiments, the at least one second epitaxy layer may be a silicon layer made pure silicon like silicon pillar. Finally, at step 1108, the more than one first epitaxy layers from the superlattice epitaxy structure may be selectively etched away or selectively removed, thereby leaving behind primarily (e.g., only) the silicon layers, which form the fishbone structure channel. The selective etching may be performed by utilizing one or more known etching techniques known in the art such as wet etching or dry etching.

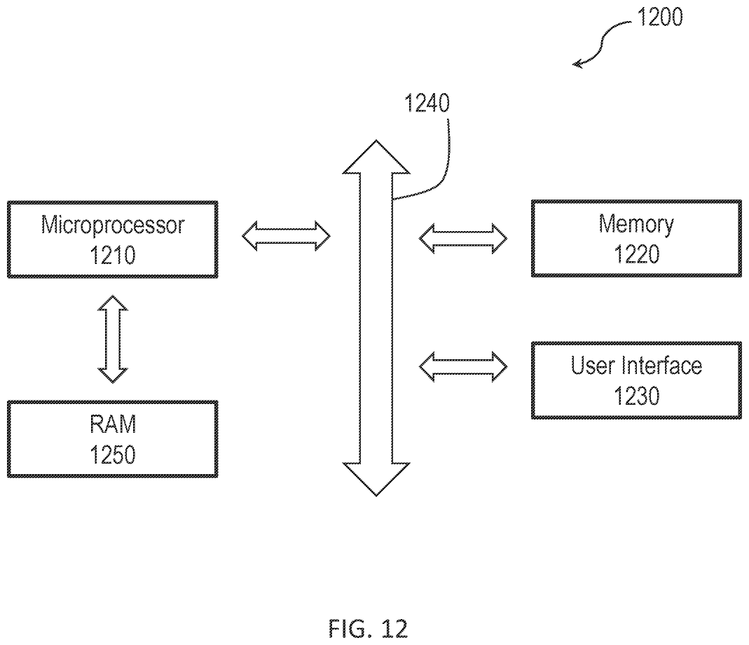

FIG. 12 illustrates a schematic block diagram of an electronic system that may implement one or more electronic devices according to one or more embodiments of the present disclosure. Referring to FIG. 12, an electronic system 1200 in accordance with one or more embodiments may include a microprocessor 1210, a memory 1220, and a user interface 1230 that perform data communication using a bus 1240. The microprocessor 1210 may include a central processing unit (CPU) or an application processor (AP). The electronic system 1200 may further include a random access memory (RAM) 1250 in communication with the microprocessor 1210. The microprocessor 1210 and/or the RAM 1250 may be implemented in a single module or package. The user interface 1230 may be used to input data to the electronic system 1200, or output data from the electronic system 1200. For example, the user interface 1230 may include a keyboard, a touch pad, a touch screen, a mouse, a scanner, a voice detector, a liquid crystal display (LCD), a micro light-emitting device (LED), an organic light-emitting diode (OLED) device, an active-matrix light-emitting diode (AMOLED) device, a printer, a lighting, or various other input/output devices without limitation. The memory 1220 may store operational codes of the microprocessor 1210, data processed by the microprocessor 1210, or data received from an external device. The memory 1220 may include a memory controller, a hard disk, or a solid state drive (SSD).

At least the microprocessor 1210, the memory 1220 and/or the RAM 1250 in the electronic system 1200 may include one or more multi-stack transistor structures described in the above embodiments.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A semiconductor device, comprising:
a substrate;
a channel portion on the substrate between a source region and a drain region, the channel portion comprising a first portion extending in a first direction and at least one second portion protruding from the first portion in a second direction crossing the first portion; and
a gate on the channel.

2. The device of claim 1, wherein the first portion comprises a first fin extending in the first direction, and the at least one second portion comprises a plurality of second fins spaced from each other along the first direction.

3. The device of claim 2, where the source region is coupled to a first end of the channel portion and the drain region is coupled to the second end of the channel portion, such that in response to a bias voltage applied to the gate, charge carriers flow between the source region and the drain region via the channel portion.

4. The device of claim 2, wherein a lowermost surface of the channel portion is directly coupled to the substrate.

5. The device of claim 2, wherein the channel portion comprises silicon (Si).

6. The device of claim 5, wherein the first fin of the channel portion has a surface orientation of 110 and the plurality of second fins has a surface orientation of 100.

7. A metal-oxide semiconductor field-effect transistor (MOSFET) comprising the semiconductor device of claim 1.

8. An integrated circuit comprising the MOSFET of claim 7.

9. A method, comprising:
growing a superlattice epitaxy structure, the superlattice epitaxy structure comprising more than one first epitaxy layers and at least one second epitaxy layer grown alternatingly one over another;
etching the more than one first epitaxy layers from the superlattice epitaxy structure;
depositing a mask at a first side and a second side of the at least one second epitaxy layer such that a center portion of the at least one second epitaxy layer is unmasked; and
growing a third epitaxy layer on the at least one second epitaxy layer at the unmasked center portion.

10. The method of claim 9, wherein a lowermost layer of the superlattice epitaxy structure and an uppermost layer of the superlattice epitaxy structure are the more than one first epitaxy layers.

11. The method of claim 9, wherein the more than one first epitaxy layers comprise silicon germanium having a suitable concentration ratio of silicon to germanium, and the at least one second epitaxy layer comprises silicon.

12. The method of claim 11, wherein the at least one second epitaxy layer comprises pure silicon.

13. The method of claim 11, wherein the etching comprising performing a selective dry etching process configured to selectively remove material having the suitable concentration ratio of silicon to germanium.

14. The method of claim 9, wherein the at least one second epitaxy layer forms a second fin in a second direction of a metal-oxide semiconductor field effect transistor (MOSFET) channel.

15. The method of claim 14, wherein the third epitaxy layer forms a first fin extending in a first direction of the MOSFET channel, the second fin protruding from the first fin in the second direction and crossing the first fin.

16. A method, comprising:
depositing a mask at a center portion of a silicon layer;
removing unmasked portions of the silicon layer;
growing a superlattice epitaxy structure at a first side and a second side of the silicon layer, the superlattice epitaxy structure comprising more than one first epitaxy layers and at least one second epitaxy layer grown alternatingly one over another, the at least one second epitaxy layer being a silicon layer; and
etching the more than one first epitaxy layers from the superlattice epitaxy structure.

17. The method of claim 16, wherein a lowermost layer of the superlattice epitaxy structure and an uppermost layer of the superlattice epitaxy structure are the more than one first epitaxy layers, the more than one first epitaxy layers comprise silicon germanium having a suitable concentration ratio of silicon to germanium.

18. The method of claim 17, wherein the etching comprising performing a selective dry etching process configured to selectively remove material having the suitable concentration ratio of silicon to germanium.

19. The method of claim 16, wherein the at least one second epitaxy layer forms a second fin in a first direction of a metal-oxide semiconductor field effect transistor (MOSFET) channel.

20. The method of claim 19, wherein the silicon layer forms a first fin extending in a first direction of the MOSFET channel, the second fin protruding from the first fin in the second direction and crossing the first fin.
